(19) United States
(12) Patent Application Publication
(10) Pub. No.: US 2015/0280068 A1
(43) Pub. Date: Oct. 1, 2015

(54) NITRIDE SEMICONDUCTOR LIGHT EMITTING DEVICE

(71) Applicant: KABUSHIKI KAISHA TOSHIBA, Tokyo (JP)

(72) Inventor: Akira TANAKA, Yokohama Kanagawa (JP)

(21) Appl. No.: 14/475,489

(22) Filed: Sep. 2, 2014

(30) Foreign Application Priority Data
Mar. 27, 2014 (JP) 2014-065979

(51) Int. Cl. H01L 33/26; H01L 33/40; H01L 33/50

(52) U.S. Cl. CPC H01L 33/26; H01L 33/50; H01L 33/405

(57) ABSTRACT

A light emitting device comprises a laminate including a first layer having a first surface on a first side of the laminate, a second layer having a second surface on the first side of the laminate, and a light emitting layer between the first layer and the second layer. A first electrode on the first side contacts the first surface and is reflective of light emitted by the light emitting layer. A second electrode on the first side contacts the second surface and extends through a recess in the laminate. The recess extends from the first surface to the second surface of the second layer. The primary light emission surface of the laminate is a surface of the second layer on a second side of the laminate. An edge of the first electrode is concentric with an edge of the second electrode.

### CROSS-REFERENCE TO RELATED APPLICATION

This application is based upon and claims the benefit of priority from Japanese Patent Application No. 2014-065979, filed Mar. 27, 2014, the entire contents of which are incorporated herein by reference.

### FIELD

Embodiments described herein relate generally to a nitride semiconductor light emitting device.

### BACKGROUND

Nitride semiconductor light emitting devices are widely used in lighting systems, display units, traffic signals and the like. In these applications, light emitting devices with reduced operating voltages and high optical output are in strong demand.

In a nitride semiconductor light emitting device, a p-side electrode and an n-side electrode are often provided on a same side of the device on which a stepped semiconductor laminate portion is also provided, and a light emission surface is provided on an opposite side of the device from the electrodes.

However, if charge carriers are concentrated and injected around a narrow peripheral region of a light emitting layer close to the n-side electrode and the p-side electrode, Auger non-radiative recombination and a carrier overflow increase, which reduces luminous efficiency and a high optical output is not obtained. The device's operating voltage also generally must increase.

### DESCRIPTION OF THE DRAWINGS

FIG. 1A is a schematic bottom view of a nitride semiconductor light emitting device according to a first embodiment, and FIG. 1B is a schematic cross-sectional view taken along line A-A.

FIG. 2A is a graph showing optical output dependence on current of the first embodiment, and FIG. 2B is a graph showing the voltage dependence on current.

FIG. 3A is a schematic bottom view of a nitride semiconductor light emitting device according to a first comparative example, and FIG. 3B is a schematic cross-sectional view taken along line A-A.

FIG. 4A is a schematic bottom view of a nitride semiconductor light emitting device according to a second embodiment, and FIG. 4B is a schematic cross-sectional view taken along line A-A.

FIG. 5A is a schematic bottom view of a nitride semiconductor light emitting device according to a second comparative example, and FIG. 5B is a schematic cross-sectional view taken along line A-A.

FIG. 6 is a schematic cross-sectional view of a nitride semiconductor light emitting device according to a third embodiment.

### DETAILED DESCRIPTION

A nitride semiconductor light emitting device in which operating voltage is reduced and optical output is increased is provided.

According to an example embodiment, a nitride semiconductor light emitting device comprises a laminate having first side and a second side opposite the first side. The laminate includes a first layer including a first conductivity type layer, the first layer having a first surface on the first side of the laminate, a second layer including a second conductivity type layer, the second layer having a second surface on the first side of the laminate and parallel to the first surface, and a light emitting layer between the first layer and the second layer that includes a nitride semiconductor. A first electrode is on the first side of the laminate and is contacting the first surface of the first layer. The first electrode is reflective of light emitted by the light emitting layer. A second electrode is on the first side of the laminate and is contacting the second surface of the second layer. The second electrode extends through a recess in the laminate. The recess extends from the first surface of the first layer to the second surface of the second layer. A primary light emission surface of the laminate is a surface of the second layer on the second side of the laminate. A first edge of the first electrode is facing the second electrode and is circular shaped in a plane parallel to the first surface. A second edge of the second electrode is facing the first electrode and is circular shaped in the plane parallel to the first surface. The first edge of the first electrode is concentric with second edge of the second electrode in the plane parallel to the first surface.

In general, according to one embodiment, a nitride semiconductor light emitting device includes a laminate, a first electrode and a second electrode. The laminate includes a first layer including a first conductivity type layer, a second layer including a second conductivity type layer, and a light emitting layer provided between the first layer and the second layer, and includes a nitride semiconductor, the laminate having in a central portion, a depressed portion which reaches the second layer from a surface of the first layer which is a side opposite to the light emitting layer. The first electrode is provided to cover the surface of the first layer, and reflects light emitted from the light emitting layer. The second electrode is provided on the second layer of a bottom of the depressed portion. A surface of the second layer which is a side opposite to a surface on which the depressed portion is provided is a light emission surface. An inner edge of the first electrode and the second electrode are concentrically arranged.

Embodiments of the present disclosure will be described with reference to the drawings.

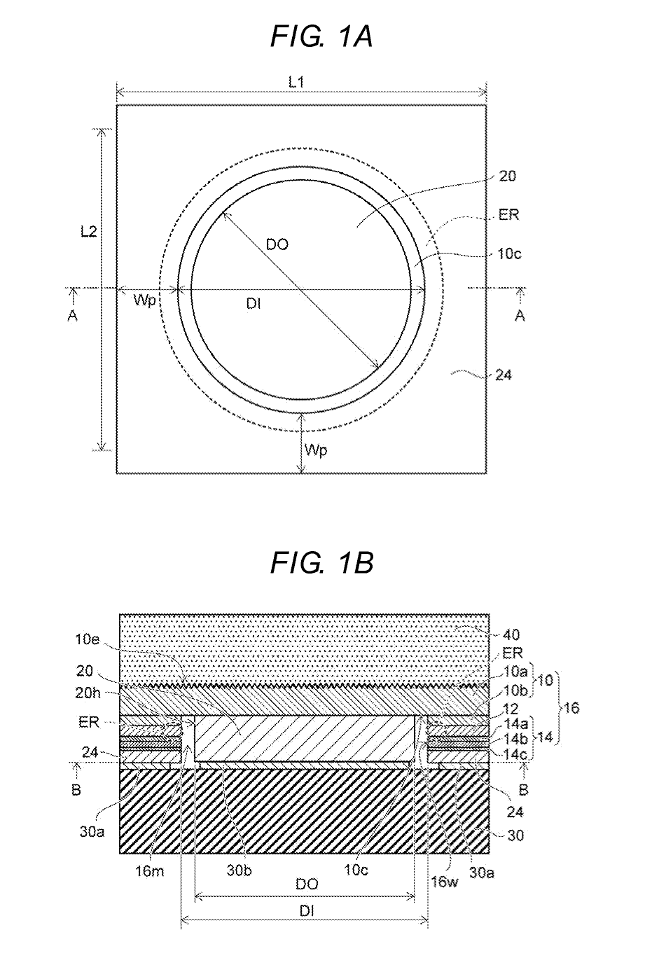

FIG. 1A is a schematic bottom view of a nitride semiconductor light emitting device according to a first embodiment, and FIG. 1B is a schematic cross-sectional view taken along line A-A.

Note that FIG. 1A is a schematic bottom view of FIG. 1B along line B-B. The nitride semiconductor light emitting device includes a laminate 16, a first electrode 24, and a second electrode 20.

The laminate 16 includes a first layer 14 including a first conductivity type layer, a second layer 10 including a second conductivity type layer, and a light emitting layer 12 provided between the first layer 14 and the second layer 10, and includes a nitride semiconductor. The laminate 16 has, in a central portion thereof, a depressed portion (recess) 16m which reaches a portion (10a) of the second layer 10 from the surface of the first layer 14. The depressed portion 16m has an inner surface 16w and a bottom surface 10c.

The first electrode 24 is provided to cover the surface of the first layer 14, and first electrode 24 reflects light emitted from the light emitting layer 12. As illustrated in FIGS. 1A and 1B, when the planar the surface of the first layer 14 substantially coincides with that of the first electrode 24, a carrier from the first electrode 24 may be efficiently injected into the light emitting layer 12. Assuming that the first electrode 24 is a p-side electrode, if first electrode 24 includes Al or Ag (at least on the side/surface facing the first layer 14), light reflectivity may be increased.

The second electrode 20 is provided on the bottom surface 10c of the depressed portion 16m. The inner edge of the first electrode 24 and the second electrode 20 are substantially concentrically arranged with each other in planar view (see e.g., FIG. 1A). In addition, the inner surface 16w of the depressed portion 16m and an outer surface 20h of the second electrode 20 may face each other and have substantially the same height (from portion 10a of second layer 10).

It is assumed that a base 30 made of, for example, a semiconductor and further includes a third electrode 30a and a fourth electrode 30b therein and/or thereon. While the laminate 16 is still on a crystal growth substrate used in the fabrication of laminate 16, the first electrode 24 of the surface of the laminate 16 and the third electrode 30a of the base 30, and the second electrode 20 and the fourth electrode 30b of the base 30 are bonded in a wafer state. That is, laminate 16 is bonded to the base 30 while still on the crystal growth substrate. After wafer bonding, the crystal growth substrate may be removed. In this way, the first electrode 24 and the second electrode 20 may be contacted easily.

The carrier injected from the first electrode 24 is supplied to the light emitting layer 12 via first layer 14. On the other hand, the carrier injected from the second electrode 20 is supplied to the light emitting layer 12 via second layer 10. Therefore, as illustrated in FIG. 1B, a (light emitting) recombination region ER is formed so as to face the outer surface 20h of the second electrode 20 in the light emitting layer 12, and a portion of the emitted light is released upward. Another portion of the emitted light moves downward, and is reflected by the first electrode 24 and may be reflected upward. A surface 10e of the second layer 10 is a light emission surface which is opposite to the surface in which the depressed portion 16m is provided. When fine unevenness (minute surface roughness, which may be referred to as a plurality of convex-concave surface features) is provided on the light emission surface, light extraction efficiency may be increased.

When a transparent resin layer 40 made of resin is provided on the light emission surface, the light emission surface may be protected and the mechanical strength of a chip may be enhanced.

Furthermore, phosphor particles may be dispersed in the transparent resin layer 40 to form a phosphor layer. The phosphor layer absorbs light emitted from the light emitting layer 12, and emits light having a wavelength longer than that of the emitted light (which may be referred to as wavelength converted light or wavelength conversion light). For example, the phosphor layer may be formed by thermal curing a resin liquid material after YAG (Yttrium-Aluminum-Garnet) phosphor particles (or other phosphors) are mixed and applied into transparent resin liquid. As a result, in the upper portion of the phosphor layer, white light may be obtained as mixed light G comprising the emitted light (from light emitting layer 12) and the wavelength conversion light (from the phosphor layer 40). Note, in some embodiments, that one side L1 of the nitride semiconductor light emitting device may be 0.6 mm, and another side L2 may be 0.6 mm, but other dimensions are possible and contemplated and L1 need not necessarily be equal to L2.

Next, the structure of the laminate 16 will be described in more detail. Note that, in the following description, the first layer 14 includes a p-type layer, and the second layer 10 includes an n-type layer, but the present disclosure is not limited to this conductive type arrangement.

The laminate 16 is formed on a sapphire or silicon substrate by crystal growth using Metal Organic Chemical Vapor Deposition (MOCVD) method or the like. The laminate 16 includes the first layer 14, the second layer 10 and the light emitting layer 12 which is provided between the first layer 14 and the second layer 10.

For example, the second layer 10 includes an n-type GaN cladding layer (donor concentration 1×10¹⁹ cm⁻³, thickness 4 μm) 10a, and a superlattice layer made of InGaN/InGaN (30 pairs of well layer thickness 1 nm and barrier layer thickness 3 nm) 10b. The superlattice layer 10b may be an undoped layer. Further, by providing the superlattice layer 10b, the crystallinity of the nitride semiconductor which tends to cause lattice mismatch (crystal defects) may be increased. For example, the light emitting layer 12 may be an InGaN/InGaN MQW (multiple quantum well) undoped layer (5.5 pairs of well layer thickness 3 nm and barrier layer thickness 5 nm).

For example, the first layer 14 includes a p-type AlGaN overflow prevention layer (acceptor concentration 1×10²⁰ cm⁻³, thickness 5 nm) 14a, a p-type cladding layer (acceptor concentration 1×10²⁰ cm⁻³, thickness 85 nm) 14b, and a p-type contact layer (acceptor concentration 1×10²¹ cm⁻³, thickness 5 nm) 14c.

In the first embodiment, the carrier injected from the second electrode 20 may be spread to the light emitting layer 12. On the other hand, since the first electrode 24 is provided to widely cover the surface of the light emitting layer 12, and the travel distance to the light emitting layer 12 is short, the carrier may be easily injected into the light emitting layer 12. Therefore, it is possible to keep Auger, non-radiative recombination probability and a carrier overflow low and thus increase the luminous efficiency. Note that Auger recombination provides energy caused by recombination with another carrier, which results in a non-radiative recombination and reduces the luminous efficiency. In addition, the higher electron concentration and the hole concentration, the higher Auger recombination probability. As a result, it is possible to suppress reduction of luminous efficiency at large current operation, and further increase the optical output.

Further, it is assumed that the second electrode 20 is an n-side electrode, electrons, which a higher mobility than that of holes, may be injected in a wide range in the horizontal direction of the light emitting layer 12. On the other hand, since the first electrode 24 (p-side electrode) is provided to widely cover the surface of the light emitting layer 12, and the travel distance to the light emitting layer 12 is short, the hole having lower mobility than that of an electron, may be easily injected into the light emitting layer 12. Therefore, it is possible to further increase the luminous efficiency. As a result, it is possible to further increase the optical output at large current operation.

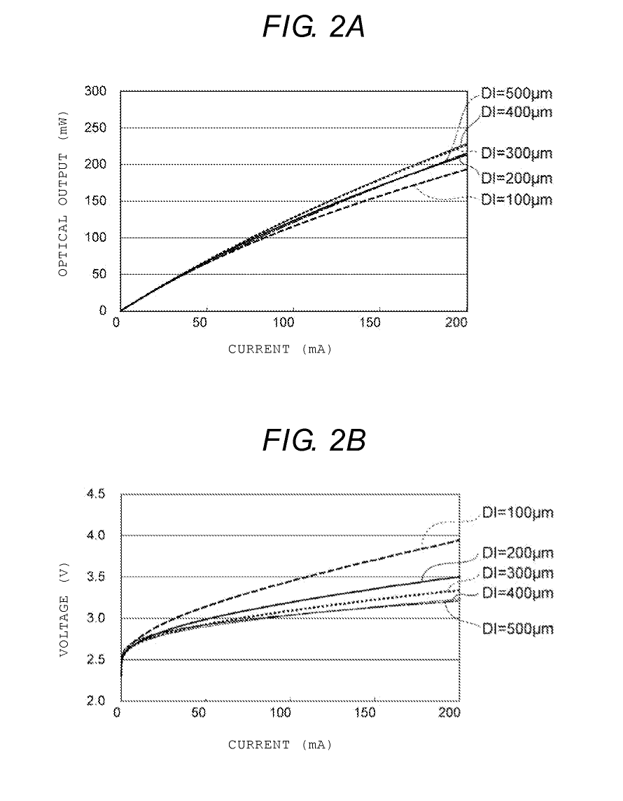

FIG. 2A is a graph illustrating optical output dependence on current in the first embodiment, and FIG. 2B is a graph showing voltage dependence on current.

It is assumed that the inner diameter DI of the first electrode 24 provided to cover the surface of the first layer 14 in which the central portion is cut is 100, 200, 300, 400 and 500 μm. Further, it is assumed that the corresponding outer diameter DO of the second electrode 20 is 80, 180, 280, 380 and 480 μm, respectively. The inner edge of the first electrode 24 and the second electrode 20 are concentrically arranged in planar view. The outer edge of the laminate 16 in these examples is L1=L2=600 μm. FIGS. 2A and 2B are graphs obtained by simulation.

As illustrated in FIG. 2A, when current Idc is 200 mA, the optical output Po is approximately 190 mW for the inner diameter DI=100 μm, the optical output is approximately 215 mW for the inner diameter DI=200 μm, and the optical output is approximately 225 mW for the inner diameter DI=300 μm; thus, the optical output is increased as the inner diameter DI is increased. Then, the optical output is 227 mW for the inner diameter DI=400 μm, in which case the optical output is almost saturated. In addition, when the inner diameter DI is increased to 500 μm, the optical output is reduced to 216 mW.

Meanwhile, as illustrated in FIG. 2B, when current Idc is 200 mA, the voltage VF in the forward direction is approximately 3.9 V for the inner diameter DI=100 μm, VF is approximately 3.5 V for the inner diameter DI=200 μm, VF is approximately 3.3 V for the inner diameter DI=300 μm and the VF is approximately 3.2 V for the inner diameter DI=400 μm; thus, the voltage VF is reduced as the inner diameter DI is increased. Further, even when the inner diameter DI is further increased to 500 μm, the voltage VF is 3.2 V; thus, the voltage VF does not decrease any more.

When DC power Pdc=Idc×VF, luminous efficiency (%) may be represented by Po/Pdc. Luminous efficiency of Idc=200 mA is 24% (DI=100 μm), 31% (DI=200 μm), 34% (DI=300 μm), 35% (DI=400 μm) and 33% (DI=500 μm).

As the inner diameter DI is increased from 100 μm to 300 μm, a recombination region area in the vicinity of the depressed portion 16m of the laminate 16 is increased. For example, it is assumed that the second electrode 20 is an n-side electrode including Au and the like, when the diameter DO of the second electrode 20 is small, the area of the recombination region ER is also small. Therefore, the carrier density is increased in a narrow region, and the luminous efficiency is reduced due to Auger recombination and a carrier overflow. That is, it is possible to increase the luminous efficiency when the internal diameter DI is equal to or higher than 200 μm. In this case, rather than the decrease in efficiency due to increased absorption by the second electrode 20 including Au and the like, uniformly spreading the carrier density may effectively increase the luminous efficiency.

On the other hand, when the inner diameter DI is 500 μm, the minimum value of the width Wp of the first electrode 24 is reduced to 50 μm. Therefore, the carrier density is too high, Auger recombination and a carrier overflow are easy to occur, and luminous efficiency decreases. That is, it is more preferable that the inner diameter DI is 200 μm or higher. Further, it is more preferable that the minimum value of the width Wp of the first electrode 24 is 50 μm or higher.

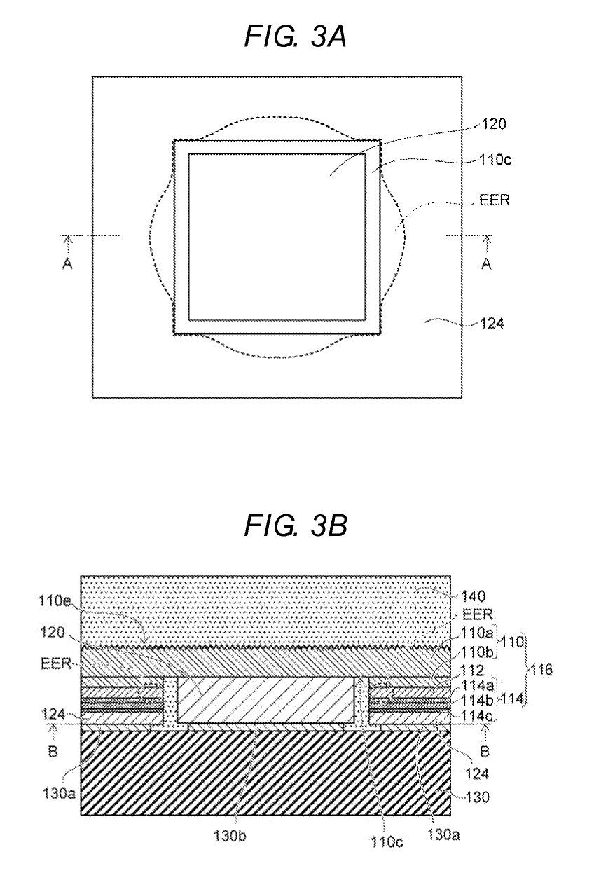

FIG. 3A is a schematic bottom view of a nitride semiconductor light emitting device according to a first comparative example, and FIG. 3B is a schematic cross-sectional view taken along line A-A.

Note that FIG. 3A is a schematic bottom view of FIG. 3B along line B-B. The nitride semiconductor light emitting device in the first comparative example includes a laminate 116, a first electrode 124, a second electrode 120 and a transparent resin layer 140.

In the first comparative example, it is assumed that a bottom surface 110c of a depressed portion 116m of the laminate 116, and the second electrode 120 are rectangles (including square) having the same center. The distance to the center of the second electrode 120 is thus longer in the direction along the diagonal (corner) than from an edge. The hole density is thus higher than the electron density at the corner. Accordingly, Auger recombination and a carrier overflow are more likely to occur, and luminous efficiency is reduced.

In contrast, in the first embodiment, the inner edge of the first electrode 24 and the second electrode 20 are concentrically arranged circular-shaped side faces. Since the carrier is moved in a direction intersecting the circumference, the carrier density may be more uniformly distributed over a large region along the circumference, thus, high optical output may be obtained while keeping high luminous efficiency.

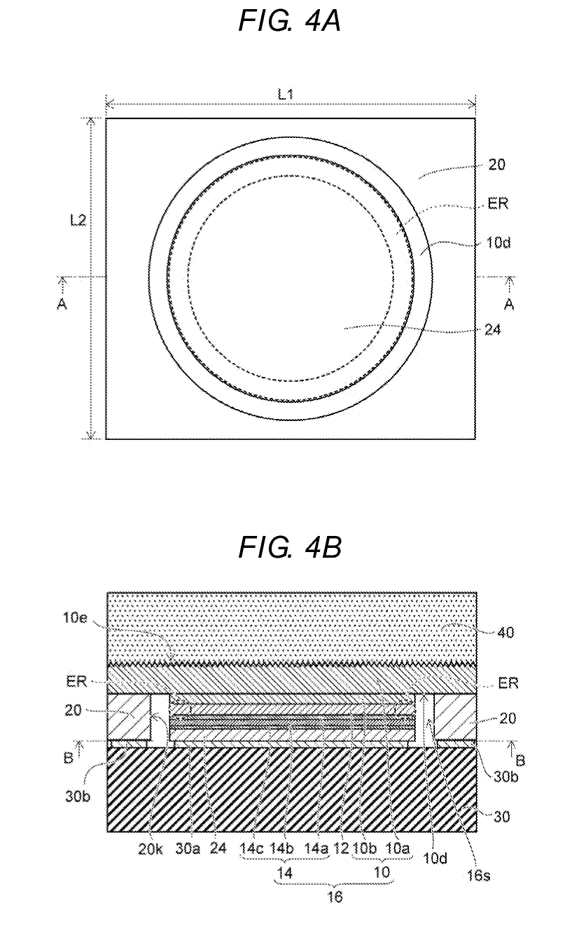

FIG. 4A is a schematic bottom view of a nitride semiconductor light emitting device according to a second embodiment, and FIG. 4B is a schematic cross-sectional view taken along line A-A.

The semiconductor light emitting device of the second embodiment includes the laminate 16 including a nitride semiconductor, the first electrode 24, and the second electrode 20.

The laminate 16 has the first layer 14 including a first conductivity type layer, the second layer 10 including a second conductivity type layer, and the light emitting layer 12 provided between the first layer 14 and the second layer 10. The laminate 16 includes, in an outer peripheral portion, a stepped portion 16s which reaches the second layer 10 from the surface of the first layer 14, which is on the opposite side to the light emitting layer 12.

The first electrode 24 is provided to cover the surface of the first layer 14, and reflects light emitted from the light emitting layer 12. The second electrode 20 is provided on the n-type GaN cladding layer 10a of the second layer 10 of the bottom surface 10d of the stepped portion 16s.

The surface 10e of the second layer 10 is a light emission surface on the side opposite to the surface on which the stepped portion 16s is provided. The first electrode 24 and an inner edge 20k of the second electrode 20 are concentrically arranged. Accordingly, Auger recombination and a carrier overflow are suppressed, thus, it is possible to increase the luminous efficiency.

When the transparent resin layer 40 is provided on the light emission surface, the light emission surface may be protected and the mechanical strength of a chip may be enhanced. Furthermore, phosphor particles may be dispersed in the transparent resin layer 40 to form a phosphor layer. The phosphor layer absorbs light emitted from the light emitting layer 12, and emits light (wavelength conversion light) having a wavelength longer than that of the emitted light.

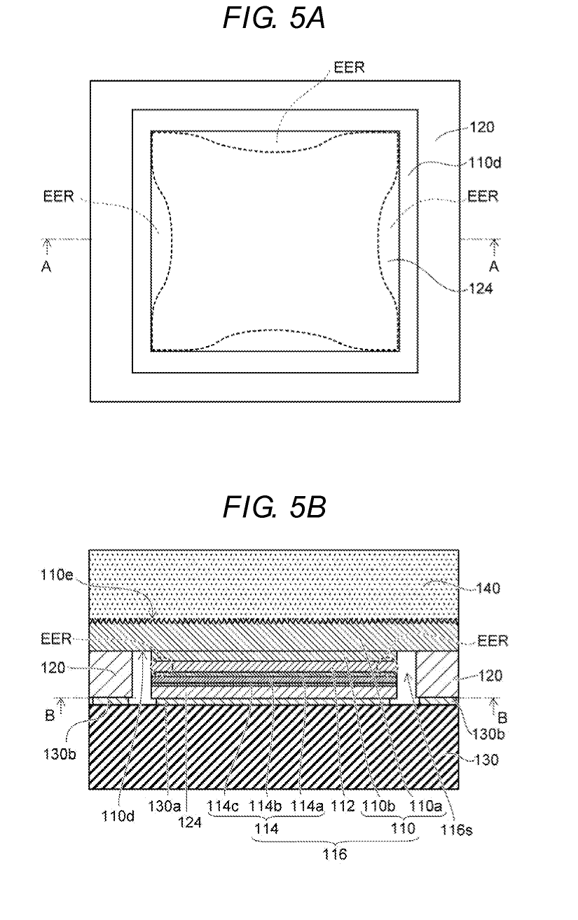

FIG. 5A is a schematic bottom view of a nitride semiconductor light emitting device according to a second comparative example, and FIG. 5B is a schematic cross-sectional view taken along line A-A.

Note that FIG. 5A is a schematic bottom view of FIG. 5B along line B-B. The nitride semiconductor light emitting device according to the second comparative example includes the laminate 116, the first electrode 124, the second electrode 120 and the transparent resin layer 140.

In the second comparative example, it is assumed that the bottom surface 110c of a stepped portion 116s of the laminate 116, and the second electrode 120 are rectangles (including square) having the same center. The distance to the center of the first electrode 124 from the second electrode 120 is longer in the direction along the diagonal (corner) than from an edge. The electron density is thus higher than the hole density at the corner, the carrier balance is upset, and radiative recombination is less likely to occur. Accordingly, Auger recombination and a carrier overflow are more likely to occur, and luminous efficiency is reduced. The wavelength conversion light becomes uneven since carrier becomes uneven. Therefore, the mixed light of the emitted light from the light emitting layer 12 and the wavelength conversion light generates color irregularity between the side and the corner.

In contrast, in the second embodiment, the carrier density may be uniformly distributed in the circumferential direction. Therefore, it is possible to keep high luminous efficiency and reduce color irregularity.

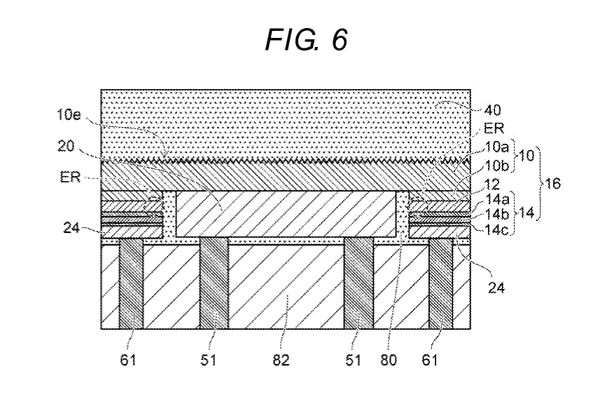

FIG. 6 is a schematic cross-sectional view of a nitride semiconductor light emitting device according to a third embodiment.

The third embodiment depicts a laminate 16 which is not bonded to a base 30. In the structure of FIG. 6, the laminate 16, the first electrode 24, and the second electrode 20 are covered with an insulating layer 80, which may be a resin material and/or an insulating material. An opening (recess) is provided in the insulating layer 80 so that surfaces of electrodes 20 and 24 may be exposed and a first pillar electrode 61 and a second pillar electrode 51 may be formed.

Thereafter, for example, using a photoresist as a mask, the first pillar electrode 61 made of copper or the like which is connected to the first electrode 24, and the second pillar electrode 51 made of copper or the like which is connected to the second electrode 20, are formed by plating. Furthermore, the photoresist and the like are removed and reinforcing resin layer 82 is supplied.

When the thickness of the first pillar electrode 61, the second pillar electrode 51 and the reinforcing resin layer 82 is 50 to 300 μm, the mechanical strength of the chip may be increased. Therefore, the crystal growth substrate may be removed, and the transparent resin layer 40 may be provided on the surface of the exposed first conductivity type layer 22. That is, it is possible to perform packaging at the wafer level without bonding to an insulating support substrate (e.g. base 30). Further, for example, the reinforcing resin layer 82 may be one having a light-shielding or light absorbing property.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nitride semiconductor light emitting device, comprising:
a laminate having first side and a second side opposite the first side and that includes:
a first layer including a first conductivity type layer, the first layer having a first surface on the first side of the laminate,
a second layer including a second conductivity type layer, the second layer having a second surface on the first side of the laminate and parallel to the first surface, and
a light emitting layer between the first layer and the second layer and including a nitride semiconductor;
a first electrode on the first side of the laminate and contacting the first surface of the first layer, the first electrode being reflective of light emitted by the light emitting layer; and
a second electrode on the first side of the laminate and contacting the second surface of the second layer and extending through a recess in the laminate, the recess extending from the first surface of the first layer to the second surface of the second layer, wherein
a primary light emission surface of the laminate is a surface of the second layer on the second side of the laminate,
a first edge of the first electrode that is facing the second electrode is circular shaped in a plane parallel to the first surface,
a second edge of the second electrode that is facing the first electrode is circular shaped in the plane parallel to the first surface, and
the first edge of the first electrode is concentric with second edge of the second electrode in the plane parallel to the first surface.

2. The device according to claim 1, wherein the first electrode surrounds the recess in the plane parallel to the first surface.

3. The device according to claim 2, wherein the recess is circular shaped and has a diameter in the plane parallel to the first surface that is at least 200 μm.

4. The device according to claim 3, wherein the first electrode has a third edge that is rectangular shaped and surrounds the first edge in the plane parallel to the first surface.

5. The device according to claim 4, wherein a distance from the first edge to the third edge is not less than 50 μm.

6. The device according to claim 1, wherein the recess surrounds the first electrode in the plane parallel to the first surface.

7. The device according to claim 6, wherein the second electrode has a fourth edge that is rectangular shaped and surrounds the second edge in the plane parallel to the first surface.

8. The device according to claim 1, further comprising:
a transparent resin layer on the primary light emission surface.

9. The device according to claim 8, wherein the transparent resin layer includes a phosphor.

10. A nitride semiconductor light emitting device, comprising:
a laminate that includes:
a first layer including a first conductivity type layer,
a second layer including a second conductivity type layer, and
a light emitting layer between the first layer and the second layer and including a nitride semiconductor, the laminate having, in an outer peripheral portion, a recess portion which reaches the second layer from a first surface of the first layer;
a first electrode on the first surface of the first layer and reflective of light emitted by the light emitting layer; and
a second electrode on a second surface of the second layer that is a bottom surface of the recess portion, wherein
a third surface of the second layer which is opposite the second surface is a primary light emission surface, and
an inner edge of the second electrode and an outer edge first electrode face each other and are concentrically arranged in a plane parallel to the first surface.

11. The nitride semiconductor light emitting device according to claim 10, wherein an outer surface of the stepped portion and an inner surface of the second electrode face each other.

12. The nitride semiconductor light emitting device according to claim 10, further comprising:
a transparent resin layer on the third surface of the second layer.

13. The nitride semiconductor light emitting device according to claim 12, wherein the transparent resin layer includes a phosphor.

14. The nitride semiconductor light emitting device according to claim 10, wherein an outer edge of the second electrode is rectangular.

15. A nitride semiconductor light emitting device, comprising:
a laminate that includes:
a first layer including a first conductivity type layer,
a second layer including a second conductivity type layer, and
a light emitting layer between the first layer and the second layer and including a nitride semiconductor, the laminate having, in a central portion, a recess portion which reaches the second layer from a first surface of the first layer;
a first electrode on the first surface of the first layer and reflective of light emitted by the light emitting layer; and
a second electrode on a second surface of the second layer that is a bottom surface of the recess portion, wherein
a third surface of the second layer which is opposite the second surface is a primary light emission surface, and
an outer edge of the second electrode and an inner edge first electrode face each other and are concentrically arranged in a plane parallel to the first surface.

16. The device according to claim 15, wherein the first electrode surrounds the recess portion in the plane parallel to the first surface.

17. The device according to claim 16, wherein the recess portion is circular shaped and has a diameter in the plane parallel to the first surface is at least 200 μm.

18. The device according to claim 17, wherein the first electrode has an outer edge that is rectangular shaped and surrounds the first edge in the plane parallel to the first surface.

19. The device according to claim 18, wherein a distance from the inner edge to the outer edge of the first electrode is not less than 50 μm.

20. The device according to claim 15, wherein an inner surface of the recess portion and an outer surface of the second electrode face each other.
